(19) United States
(12) Patent Application Publication
(10) Pub. No.: US 2022/0059704 A1
(43) Pub. Date: Feb. 24, 2022

(54) TRANSISTOR CAP-CHANNEL ARRANGEMENTS

(71) Applicant: INTEL CORPORATION, Santa Clara, CA (US)

(72) Inventors: Chieh-jen Ku, Portland, OR (US); Bernhard Sell, Portland, OR (US); Pei-hua Wang, Beaverton, OR (US); Christopher J. Wiegand, Portland, OR (US)

(73) Assignee: INTEL CORPORATION, Santa Clara, CA (US)

(21) Appl. No.: 16/999,819

(22) Filed: Aug. 21, 2020

(51) Int. Cl. H01L 29/786; H01L 27/108

(52) U.S. Cl. CPC H01L 29/78696; H01L 27/108

(57) ABSTRACT

Disclosed herein are transistor cap-channel arrangements, and related methods and devices. For example, in some embodiments, a transistor cap-channel arrangement may include a channel material having a conductivity type; an insulating material; and a cap material between the channel material and the insulating material, wherein the cap material is different from the channel material and the insulating material, and the cap material has a conductivity type that is a same conductivity type as the channel material.

### BACKGROUND

Thin-film transistors may include a semiconducting channel between a gate and an interlayer dielectric. Source/drain contacts may extend through the interlayer dielectric to contact the semiconducting channel.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is a side, cross-sectional view of a transistor cap-channel arrangement, in accordance with various embodiments.

FIGS. 2-10 are side, cross-sectional views of example transistors including a transistor cap-channel arrangement, in accordance with various embodiments.

FIG. 11 is a flow diagram of an example method of manufacturing a transistor cap-channel arrangement, in accordance with various embodiments.

FIG. 12 is a top view of a wafer and dies that may include a transistor cap-channel arrangement in accordance with any of the embodiments disclosed herein.

FIG. 13 is a side, cross-sectional view of an integrated circuit (IC) device that may include a transistor cap-channel arrangement in accordance with any of the embodiments disclosed herein.

FIG. 14 is a side, cross-sectional view of an IC package that may include a transistor cap-channel arrangement in accordance with various embodiments.

FIG. 15 is a side, cross-sectional view of an IC device assembly that may include a transistor cap-channel arrangement in accordance with any of the embodiments disclosed herein.

FIG. 16 is a block diagram of an example electrical device that may include a transistor cap-channel arrangement in accordance with any of the embodiments disclosed herein.

### DETAILED DESCRIPTION

Disclosed herein are transistor cap-channel arrangements, and related methods and devices. For example, in some embodiments, a transistor cap-channel arrangement may include a channel material having a conductivity type; an insulating material; and a cap material between the channel material and the insulating material, wherein the cap material is different from the channel material and the insulating material, and the cap material has a conductivity type that is a same conductivity type as the channel material.

The electrical properties of thin-film transistors (TFTs) may be affected by subsequent manufacturing operations. For example, the threshold voltage (VT) of an n-type TFT may have an initial value when the TFT is first fabricated in an integrated circuit (IC) device, but the VT may decrease due to subsequent thermal processing. This reduction in VT may be detrimental to device performance; for example, for a TFT that is part of a memory cell (e.g., a dynamic random access memory (DRAM) cell), a negative VT may result in high leakage current in the TFT, and thus a shorter retention time of the memory cell. The performance of p-type TFTs may suffer analogously from subsequent processing (i.e., the VT of a p-type TFT may undesirably increase), and these consequences for VT may be particularly acute for back-end (or “back-end-of-line” (BEOL)) TFTs.

The transistor cap-channel arrangements disclosed herein may include a capping layer that can shift the VT of a transistor in a direction (i.e., positive or negative) to compensate for the shift in the opposite direction that may take place during subsequent processing, and may thus result in a transistor with improved electrical characteristics relative to conventional transistors. For example, an n-type TFT may include a capping layer that causes the TFT to have an initial VT that is more positive than the initial VT of conventional TFTs; during subsequent processing, the VT of the TFT may be reduced from its initial value, but may remain positive, and thus may achieve electrical performance not achievable using conventional approaches.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). For the purposes of the present disclosure, the phrase “A, B, or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. As used herein, a “high-k dielectric” refers to a material having a higher dielectric constant than silicon oxide. As used herein, a “conductivity type” refers to the p-type conductivity or n-type conductivity of a material.

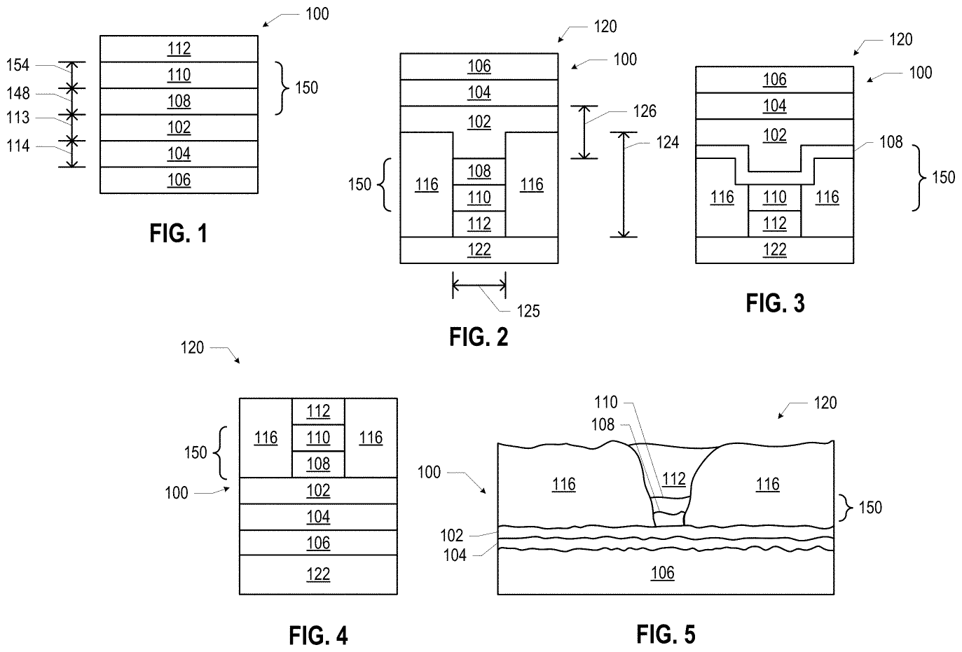

FIG. 1 is a side, cross-sectional view of a transistor cap-channel arrangement 100 including a channel material 102 and a cap stack 150, in accordance with various embodiments. The cap stack 150 may include a first cap material 108 and a second cap material 110, with the first cap material 108 between the channel material 102 and the second cap material 110. The cap stack 150 may be between an insulating material 112 and the channel material 102. The transistor cap-channel arrangement 100 may also include a gate electrode material 106, and a gate dielectric 104 disposed between the gate electrode material 106 and the channel material 102.

The channel material 102 may be composed of semiconductor material systems including, for example, n-type or p-type materials systems. The channel material 102 may include a semiconductor material (e.g., an oxide semiconductor material). In some embodiments, the channel material 102 may include indium, gallium, zinc, and oxygen (e.g., in the form of indium gallium zinc oxide (IGZO)); such a channel material 102 may have n-type conductivity. In some embodiments, the channel material 102 may include tin and oxygen (e.g., in the form of tin oxide); antimony and oxygen (e.g., in the form of antimony oxide); indium and oxygen (e.g., in the form of indium oxide); indium, tin, and oxygen (e.g., in the form of indium tin oxide); titanium and oxygen (e.g., in the form of titanium oxide); zinc and oxygen (e.g., in the form of zinc oxide); indium, zinc, and oxygen (e.g., in the form of indium zinc oxide); gallium and oxygen (e.g., in the form of gallium oxide); titanium, oxygen, and nitrogen (e.g., in the form of titanium oxynitride); ruthenium and oxygen (e.g., in the form of ruthenium oxide); or tungsten and oxygen (e.g., in the form of tungsten oxide). The channel material 102 may have a thickness 113. In some embodiments, the thickness 113 may be between 5 nanometers and 30 nanometers.

As noted above, a transistor cap-channel arrangement 100 may include a cap stack 150 including a first cap material 108 and a second cap material 110. The first cap material 108 may serve as a VT adjustment layer, shifting the VT of the transistor cap-channel arrangement 100 in a desired direction (e.g., so that subsequent processing shifting the VT in the opposite direction will result in a desired final VT). The mechanism by which this VT shift may be accomplished may include additional dipole formation, formation of a depletion region, formation of an accumulation region, and/or the introduction of new fixed charge by the presence of the first cap material 108. In some embodiments, a thickness 148 of the first cap material 108 may be between 1 Angstrom and 1 nanometer.

In some embodiments, the first cap material 108 may have a same conductivity type as the channel material 102 (i.e., the channel material 102 and the first cap material 108 may both have n-type conductivity, or the channel material 102 and the first cap material 108 may both have p-type conductivity). For example, when the channel material 102 has n-type conductivity (e.g., the channel material 102 includes IGZO), the first cap material 108 may include copper and oxygen (e.g., in the form of copper oxide); nickel and oxygen (e.g., in the form of nickel oxide); iron and oxygen (e.g., in the form of iron oxide); cobalt and oxygen (e.g., in the form of cobalt oxide); iridium and oxygen (e.g., in the form of iridium oxide); ruthenium and oxygen (e.g., in the form of ruthenium oxide); lanthanum and oxygen (e.g., in the form of lanthanum oxide); beryllium and oxygen (e.g., in the form of beryllium oxide); lithium and oxygen (e.g., in the form of lithium oxide); or calcium and oxygen (e.g., in the form of calcium oxide). In some such embodiments, the use of the first cap material 108 may shift VT of the transistor cap-channel arrangement 100 in a positive direction (e.g., by 0.4 volts in some embodiments). In another example, when the channel material 102 has p-type conductivity (e.g., the channel material 102 includes oxides of any of indium, zinc, gallium, hafnium, magnesium, aluminum, silicon, lanthanum, or zirconium), the first cap material 108 may include oxides of any of copper, nickel, cobalt, lithium, or silver.

As noted above, a cap stack 150 may include a second cap material 110 between the first cap material 108 and an insulating material 112 (e.g., in contact with the first cap material 108 and the insulating material 112). The second cap material 110 may serve a protective function, mitigating degradation of the proximate materials (e.g., the channel material 102) during subsequent processing operations. In some embodiments, the second cap material 110 may include oxygen (e.g., in the form of an oxide material) or nitrogen (e.g., in the form of a nitride material). In some embodiments, the second cap material 110 may include gallium and oxygen (e.g., in the form of gallium oxide); aluminum and oxygen (e.g., in the form of aluminum oxide); hafnium and oxygen (e.g., in the form of hafnium oxide); zirconium and oxygen (e.g., in the form of zirconium oxide); silicon and oxygen (e.g., in the form of silicon oxide); or silicon and nitrogen (e.g., in the form of silica nitride). In some embodiments, a thickness 154 of the second cap material 110 may be between 5 Angstroms and 2 nanometers. In some embodiments, the second cap material 110 may not be present in a cap stack 150.

The insulating material 112 may include any suitable dielectric materials. In some embodiments, the insulating material 112 may include an interlayer dielectric (ILD), which may include silicon and oxygen (e.g., in the form of silicon oxide); silicon and nitrogen (e.g., in the form of silicon nitride); aluminum and oxygen (e.g., in the form of aluminum oxide); and/or silicon, oxygen, and nitrogen (e.g., in the form of silicon oxynitride).

The gate electrode material 106 may include at least one p-type work function metal or n-type work function metal, depending on whether the transistor cap-channel arrangement 100 is to be included in a p-type metal oxide semiconductor (PMOS) transistor or an n-type metal oxide semiconductor (NMOS) transistor. For a PMOS transistor, metals that may be used for the gate electrode material 106 may include, but are not limited to, ruthenium, palladium, platinum, cobalt, nickel, and conductive metal oxides (e.g., ruthenium oxide). For an NMOS transistor, metals that may be used for the gate electrode material 106 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 106 may consist of a stack of two or more metal layers, where one or more metal layers are work function metal layers and at least one metal layer is a fill metal layer. Further metal layers may be included for other purposes, such as to act as a barrier layer.

The gate dielectric 104 may be between the channel material 102 and the gate electrode material 106 (e.g., may be in contact with the channel material 102 and the gate electrode material 106). The gate dielectric 104 may be a high-k dielectric, and may include one or more layers of material. The gate dielectric 104 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 104 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 104 during manufacture of the transistor cap-channel arrangement 100 to improve the quality of the gate dielectric 104. The gate dielectric 104 may have a thickness 114. In some embodiments, the thickness 114 may be between 0.5 nanometers and 3 nanometers (e.g., between 1 nanometer and 3 nanometers, or between 1 nanometer and 2 nanometers).

A transistor cap-channel arrangement 100 may be included in any suitable transistor structure. For example, FIGS. 2-8 are side, cross-sectional views of example transistors 120 (e.g., TFTs) including a transistor cap-channel arrangement 100, and FIGS. 9-10 are side, cross-sectional views of example arrays of transistors 120 including transistor cap-channel arrangements 100. The transistors 120 illustrated in FIGS. 2-10 do not represent an exhaustive set of transistor structures in which a transistor cap-channel arrangement 100 may be included, but provide examples of such transistor structures. Note that FIGS. 2-10 are intended to show relative arrangements of the components therein, and that transistors 120 may include other components that are not illustrated (e.g., electrical contacts to the source/drain (S/D) materials 116 to transport current in and out of the transistors 120, electrical contacts to the gate electrode material 106, etc.). Any of the components of the transistors 120 discussed below with reference to FIGS. 2-10 may take the form of any of the embodiments of those components discussed above with reference to FIG. 1. Additionally, although various components of the transistors 120 are illustrated in FIGS. 2-10 as being planar rectangles or formed of rectangular solids, this is simply for ease of illustration, and embodiments of these transistors 120 may be curved, rounded, or otherwise irregularly shaped as dictated by the manufacturing processes used to fabricate the transistors 120.

FIG. 2 depicts a transistor 120 including a transistor cap-channel arrangement 100 and having a “top” gate provided by the gate electrode material 106 and the gate dielectric 104. The gate dielectric 104 may be disposed between the gate electrode material 106 and the channel material 102. In the embodiment of FIG. 2, the transistor cap-channel arrangement 100 is shown as disposed on a substrate 122. The substrate 122 may be any structure on which the transistor cap-channel arrangement 100, or other elements of the transistor 120, is disposed. In some embodiments, the substrate 122 may include a semiconductor, such as silicon. In some embodiments, the substrate 122 may include an insulating layer, such as an oxide isolation layer, or one or more layers of a metallization stack (e.g., when the transistor 120 is a back-end transistor, as discussed below with reference to FIG. 13. For example, the substrate 122 may include a semiconductor material (e.g., any of the materials discussed below with reference to the substrate 1602 of FIG. 13) and an ILD in one or more metallization layers (e.g., discussed below with reference to FIG. 13) disposed between the semiconductor material and the S/D materials 116 and the channel material 102. Any suitable ones of the embodiments of the substrate 122 described with reference to FIG. 2 may be used for the substrates 122 of others of the transistors 120 disclosed herein.

As noted above, the transistor 120 of FIG. 2 may include S/D materials 116 on the substrate 122, with the channel material 102 disposed between the S/D materials 116 so that at least some of the channel material 102 is coplanar with at least some of the S/D materials 116. Further, the cap stack 150 may be entirely between the S/D materials 116 (i.e., the first cap material 108 may not extend between the S/D materials 116 and the channel material 102, and the first cap material 108 and the second cap material 110 may be between the S/D materials 116). Thus, in the transistor 120 of FIG. 2, the S/D materials 116 may “land” directly on the channel material 102. The S/D materials 116 may have a thickness 124, and the channel material 102 may have a thickness 126; the thickness 124 may be greater than the thickness 126, as illustrated. The S/D materials 116 may be spaced apart by a distance 125 that may be, for example, between 20 nanometers and 30 nanometers (e.g., between 22 nanometers and 28 nanometers, or approximately 25 nanometers).

The S/D materials 116 may be formed using any suitable processes known in the art. For example, one or more layers of metal and/or metal alloys may be deposited or otherwise provided to form the S/D materials 116, as known for TFTs based on semiconductor oxide systems. Any suitable ones of the embodiments of the S/D materials 116 described above with reference to FIG. 2 may be used for any of the S/D materials 116 described herein.

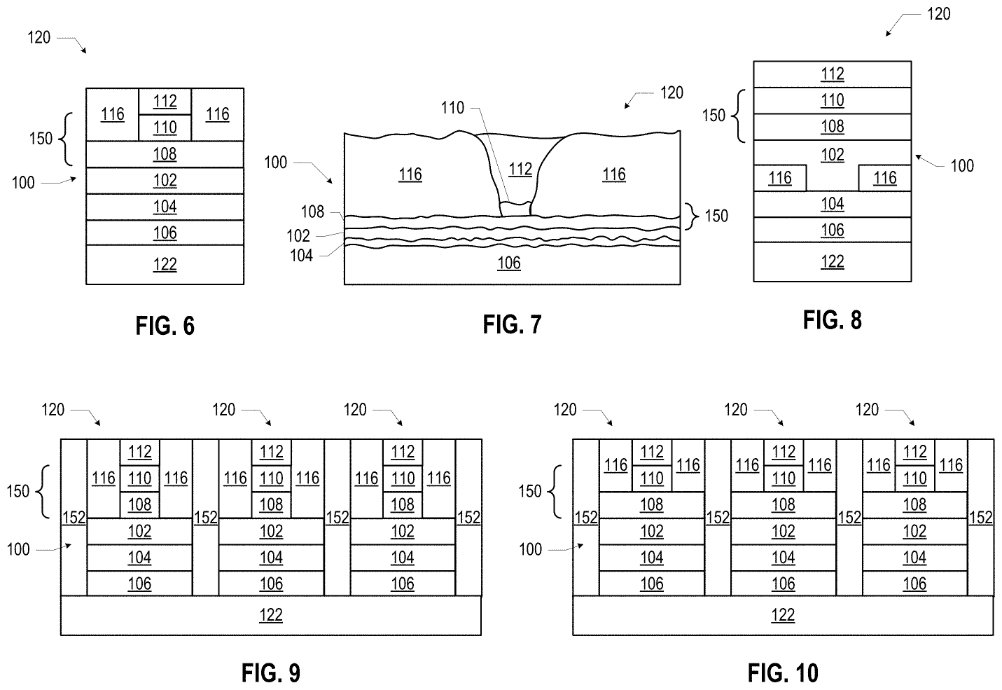

FIG. 3 depicts another transistor 120 including a transistor cap-channel arrangement 100 and having a “top” gate provided by the gate electrode material 106 and the gate dielectric 104. The transistor 120 of FIG. 3 shares many features with the transistor 120 of FIG. 2, but in the transistor 120 of FIG. 3, the cap stack 150 may not be entirely between the S/D materials 116. In particular, in the transistor 120 of FIG. 3, the first cap material 108 may extend between the S/D materials 116 and the channel material 102, while the second cap material 110 may be between the S/D materials 116 (and may not extend between the S/D materials 116). As shown, in the transistor 120 of FIG. 3, the S/D materials 116 may “land” on the first cap material 108 so that the first cap material 108 is between the S/D materials 116 and the channel material 102. Thus, in various embodiments, S/D materials 116 of a transistor 120 may land directly on the channel material 102 (e.g., as discussed above with reference to FIG. 2, and as shown in FIGS. 4-5 and discussed below) or may land on the first cap material 108 (e.g., as discussed above with reference to FIG. 3, and as shown in FIGS. 6-7 and discussed below) so that the first cap material 108 is between the S/D materials 116 and the channel material 102.

FIG. 4 depicts a transistor 120 including a transistor cap-channel arrangement 100 and having a “bottom” gate provided by the gate electrode material 106 and the gate dielectric 104. The gate dielectric 104 may be disposed between the gate electrode material 106 and the channel material 102. In the embodiment of FIG. 4, the gate electrode material 106 may be disposed between the substrate 122 and the channel material 102. The transistor 120 may include S/D materials 116 disposed on the channel material 102 such that the S/D materials 116 are not coplanar with the channel material 102. Further, as discussed above with reference to FIG. 2, the cap stack 150 may be entirely between the S/D materials 116 (i.e., the first cap material 108 may not extend between the S/D materials 116 and the channel material 102, and the first cap material 108 and the second cap material 110 may be between the S/D materials 116). Thus, in the transistor 120 of FIG. 4, the S/D materials 116 may “land” directly on the channel material 102.

FIG. 5 depicts a transistor 120 having the structure of the transistor 120 of FIG. 4. In particular, the transistor 120 of FIG. 5 includes a transistor cap-channel arrangement 100, has a single “bottom” gate provided by the gate electrode material 106 and the gate dielectric 104, and the S/D materials 116 are in contact with the channel material 102 (with the cap stack 150 between the S/D materials 116). The transistor 120 of FIG. 5 may also include a substrate 122 (not shown) arranged so that the gate electrode material 106 is disposed between the substrate 122 and the gate dielectric 104. The transistor 120 may include S/D materials 116 disposed on the channel material 102 such that S/D materials 116 are not coplanar with the channel material 102.

FIG. 6 depicts a transistor 120 including a transistor cap-channel arrangement 100 and having a “bottom” gate provided by the gate electrode material 106 and the gate dielectric 104. The gate dielectric 104 may be disposed between the gate electrode material 106 and the channel material 102. In the embodiment of FIG. 6, the gate electrode material 106 may be disposed between the substrate 122 and the channel material 102. The transistor 120 may include S/D materials 116 disposed on the channel material 102 such that the S/D materials 116 are not coplanar with the channel material 102. Further, as discussed above with reference to FIG. 2, the cap stack 150 may not be entirely between the S/D materials 116. In particular, in the transistor 120 of FIG. 6, the first cap material 108 may extend between the S/D materials 116 and the channel material 102, while the second cap material 110 may be between the S/D materials 116 (and may not extend between the S/D materials 116). As shown, in the transistor 120 of FIG. 6, the S/D materials 116 may “land” on the first cap material 108.

FIG. 7 depicts a transistor 120 having the structure of the transistor 120 of FIG. 6. In particular, the transistor 120 of FIG. 7 includes a transistor cap-channel arrangement 100, has a single “bottom” gate provided by the gate electrode material 106 and the gate dielectric 104, and the S/D materials 116 are in contact with the first cap material 108 of the cap stack 150 (with the second cap material 110 between the S/D materials 116) so that the first cap material 108 is between the S/D materials 116 and the channel material 102. The transistor 120 of FIG. 7 may also include a substrate 122 (not shown) arranged so that the gate electrode material 106 is disposed between the substrate 122 and the gate dielectric 104. The transistor 120 may include S/D materials 116 disposed on the first cap material 108 such that S/D materials 116 are not coplanar with the channel material 102.

FIG. 8 depicts a transistor 120 including a transistor cap-channel arrangement 100 and having a “bottom” gate provided by the gate electrode material 106 and the gate dielectric 104. The gate dielectric 104 may be disposed between the gate electrode material 106 and the channel material 102. In the embodiment of FIG. 8, the gate electrode material 106 may be disposed between the substrate 122 and the channel material 102. The transistor 120 may include the channel material 102 disposed on the S/D materials 116 such that at least some of the S/D materials 116 are coplanar with at least some of the channel material 102. In some embodiments, the S/D materials 116 may be individually disposed between some of the channel material 102 and the substrate 122, as illustrated in FIG. 8, while in other embodiments, the channel material 102 may not extend “above” the S/D materials 116. In some embodiments, the channel material 102 may conform around the S/D materials 116. The cap stack 150 may be disposed above the channel material 102 such that the S/D materials 116 are between the cap stack 150 and the gate electrode material 106 (and, in some embodiments, at least some of the channel material 102 is between the cap stack 150 and the S/D materials 116).

Any of the transistors 120 disclosed herein may be included in an array of transistors 120. Such an array of transistors 120 may be part of an array of memory cells including those transistors 120 (e.g., an array of DRAM cells that also include capacitors, not shown). For example, FIGS. 9 and 10 are side, cross-sectional views of arrays of transistors 120. In particular, the transistors 120 included in FIG. 9 are the transistors 120 of FIGS. 4 and 5, and the transistors 120 included in FIG. 10 are the transistors 120 of FIGS. 6 and 7). Adjacent transistors 120 may be separated by insulating material 152, which may be any suitable dielectric material (e.g., an ILD or other isolation material).

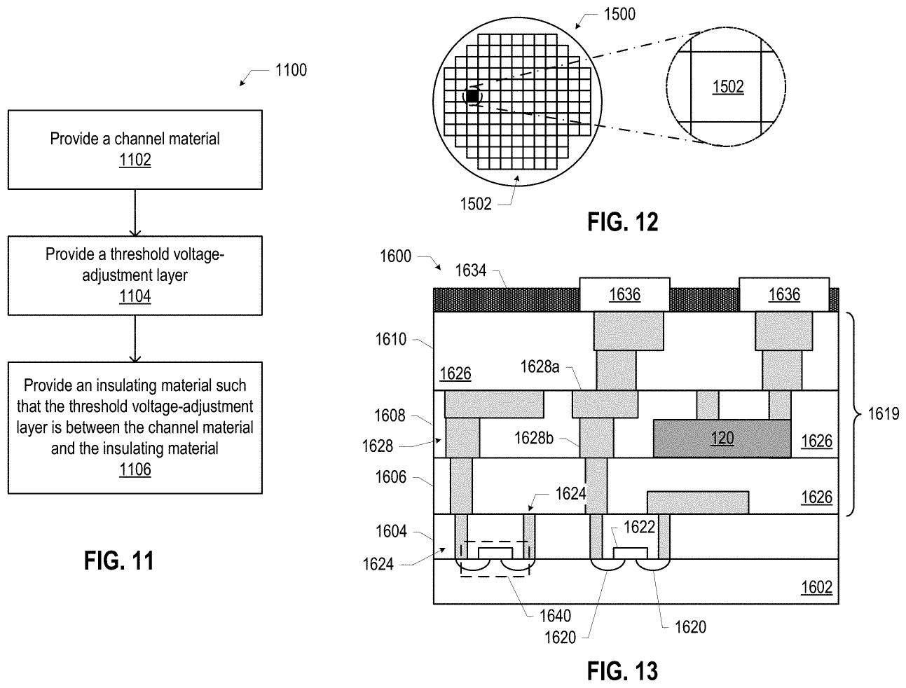

The transistor cap-channel arrangements 100 disclosed herein may be manufactured using any suitable techniques. For example, FIG. 11 is a flow diagram of an example method 1100 of manufacturing a transistor cap-channel arrangement, in accordance with various embodiments. Although the operations of the method 1100 are illustrated once each and in a particular order, the operations may be performed in any suitable order and repeated as desired. For example, one or more operations may be performed in parallel to manufacture multiple transistor cap-channel arrangements substantially simultaneously. In another example, the operations may be performed in a different order to reflect the structure of a transistor in which the transistor cap-channel arrangement will be included (e.g., the cap stack 150 of the transistor 120 of FIG. 2 may be provided before channel material 102, while the cap stack 150 of the transistor 120 of FIG. 4 may be provided after the channel material 102).

At 1102, a channel material may be provided. The channel material provided at 1102 may take the form of any of the embodiments of the channel material 102 disclosed herein (e.g., any of the embodiments discussed herein with reference to a transistor 120). The channel material may be provided at 1102 using any suitable deposition and patterning technique known in the art (e.g., chemical vapor deposition (CVD), physical vapor deposition (PVD), or atomic layer deposition (ALD)).

At 1104, a threshold voltage-adjustment layer may be provided. The threshold voltage-adjustment layer provided at 1104 may adjust the threshold voltage (VT) of the transistor in which the threshold voltage-adjustment layer is included, and in some embodiments, may take the form of any of the first cap materials 108 disclosed herein, for example (e.g., any of the embodiments discussed herein with reference to a transistor 120). The threshold voltage-adjustment layer may be provided at 1104 using any suitable deposition and patterning technique known in the art. In some embodiments in which the threshold voltage-adjustment layer includes oxygen, the threshold voltage-adjustment layer may be provided at 1104 by depositing a metallic film that is oxidized during subsequent manufacturing operations (e.g., by the deposition of a second cap material 110 and/or an insulating material 112).

At 1106, an insulating material may be provided such that the threshold voltage-adjustment layer is between the channel material and the insulating material. The insulating material provided at 1104 may take the form of any of the embodiments of the insulating material 112 disclosed herein and/or may take the form of any of the embodiments of the second cap material 110 disclosed herein, for example (e.g., any of the embodiments discussed herein with reference to a transistor 120). The insulating material may be provided 1106 using any suitable deposition and patterning technique known in the art.

The method 1100 may further include other manufacturing operations related to fabrication of other components of a transistor 120. For example, the method 1100 may include providing S/D materials (e.g., in accordance with any suitable ones of the embodiments of the S/D materials 116 discussed above), forming conductive contacts to various portions of the transistor-channel arrangement, etc.

The transistor cap-channel arrangements 100 and transistors 120 disclosed herein may be included in any suitable electronic component. FIGS. 12-16 illustrate various examples of apparatuses that may include any of the transistor cap-channel arrangements 100 and transistors 120 disclosed herein.

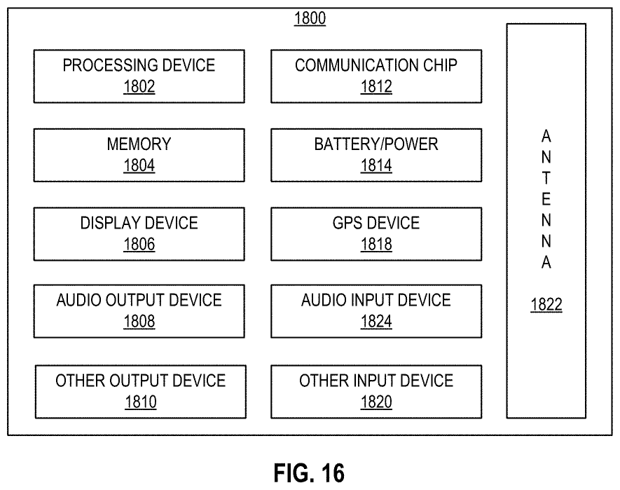

FIG. 12 is a top view of a wafer 1500 and dies 1502 that may include one or more transistor cap-channel arrangements 100 in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC (e.g., ICs including one or more of any of the transistors 120 disclosed herein). After the fabrication of the semiconductor product is complete, the wafer 1500 may undergo a singulation process in which the dies 1502 are separated from one another to provide discrete “chips” of the semiconductor product. In particular, devices that include a transistor cap-channel arrangement 100 as disclosed herein may take the form of the wafer 1502 (e.g., not singulated) or the form of the die 1502 (e.g., singulated). The die 1502 may include one or more transistors (e.g., one or more of the transistors 120 or the transistors 1640 discussed below with reference to FIG. 13) and/or supporting circuitry to route electrical signals to the transistors, as well as any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 16) or other logic that is configured to store information in the memory devices or execute instructions stored in the memory array.

FIG. 13 is a side, cross-sectional view of an IC device 1600 that may include one or more transistor cap-channel arrangements 100 and/or transistors 120 in accordance with any of the embodiments disclosed herein. One or more of the IC devices 1600 may be included in one or more dies 1502 (FIG. 12). The IC device 1600 may be formed on a substrate 1602 (e.g., the wafer 1500 of FIG. 12) and may be included in a die (e.g., the die 1502 of FIG. 12). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 12) or a wafer (e.g., the wafer 1500 of FIG. 12).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 13 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors. In some embodiments, one or more of the transistors 1640 may include one or more transistor cap-channel arrangements 100 in accordance with any of the embodiments disclosed herein. For example, a transistor 1640 may take the form of any of the transistors 120 disclosed herein. The S/D regions 1620 may include the S/D materials 116. Transistors 120 including the transistor cap-channel arrangements 100 disclosed herein may be particularly advantageous when used in the metal layers of a microprocessor device for analog circuitry, logic circuitry, or memory circuitry, and may be formed along with existing complementary metal oxide semiconductor (CMOS) processes.

Each transistor 1640 may include a gate 1622 formed of at least two layers, a gate dielectric layer and a gate electrode layer. The gate electrode layer may take the form of any of the embodiments of the gate electrode material 106 disclosed herein. The gate dielectric layer may take the form of any of the embodiments of the gate dielectric 104 disclosed herein. Generally, the gate dielectric layer of a transistor 1640 may include one layer or a stack of layers, and the one or more layers may include silicon oxide, silicon dioxide, silicon carbide, and/or a high-k dielectric material.

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers. In some embodiments, the gate electrode may consist of a V-shaped structure (e.g., when the fin does not have a “flat” upper surface, but instead has a rounded peak).

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may take the form of any of the embodiments of the S/D materials 116 discussed above with reference to the transistors 120. In other embodiments, the S/D regions 1620 may be formed using any suitable processes known in the art. For example, the S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., the transistors 1640) of the device layer 1604 through one or more interconnect layers disposed on the device layer 1604 (illustrated in FIG. 13 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600. In some embodiments, one or more transistors 120 may be disposed in one or more of the interconnect layers 1606-1610, in accordance with any of the techniques disclosed herein. FIG. 13 illustrates a single transistor 120 in the interconnect layer 1608 for illustration purposes, but any number and structure of transistors 120 may be included in any one or more of the layers in a metallization stack 1619 (e.g., an array of transistors 120, as illustrated in FIGS. 9-10). A transistor 120 included in the metallization stack 1619 may be referred to as a “back-end” device. One or more transistors 120 in the metallization stack 1619 may be coupled to any suitable ones of the devices in the device layer 1604, to other components (e.g., a capacitor in the metallization stack 1619 as part of a DRAM cell) and/or to one or more of the conductive contacts 1636 (discussed below).

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 13). Although a particular number of interconnect layers 1606-1610 is depicted in FIG. 13, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 13. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 13. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 13, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

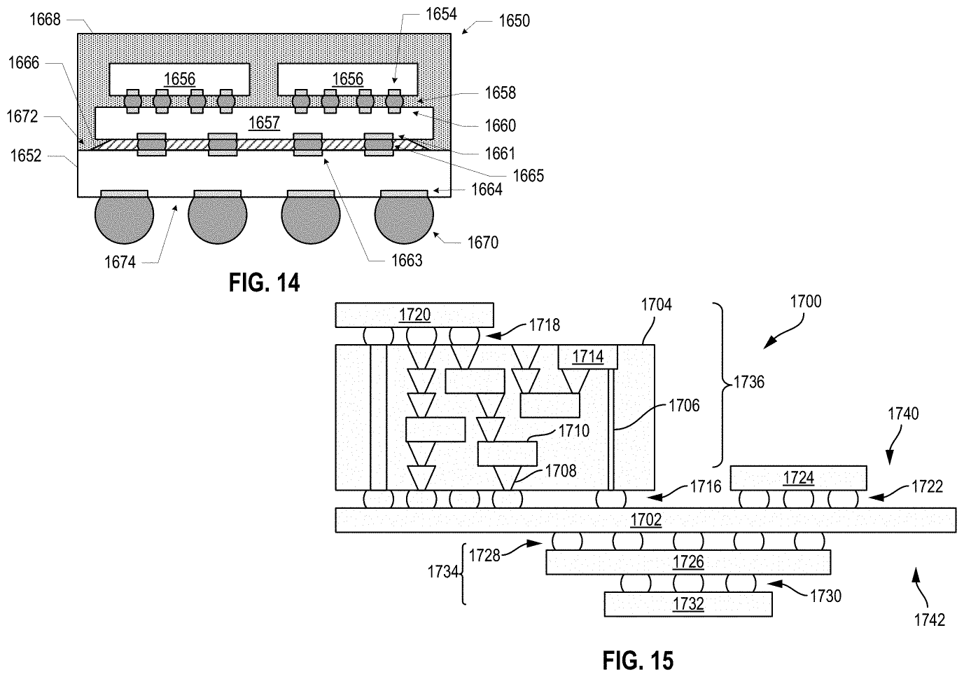

FIG. 14 is a side, cross-sectional view of an example IC package 1650 that may include one or more transistor cap-channel arrangements 100 and/or transistors 120 in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnect structures 1628 discussed above with reference to FIG. 13.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to other devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 14 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 14 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 14 are solder balls (e.g., for a ball grid array arrangement), but any suitable second-level interconnects 16770 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 15.

The dies 1656 may take the form of any of the embodiments of the die 1502 discussed herein (e.g., may include any of the embodiments of the IC device 1600, and may include any of the transistor cap-channel arrangements 100 and/or transistors 120 disclosed herein). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory).

Although the IC package 1650 illustrated in FIG. 14 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 14, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 15 is a side, cross-sectional view of an IC device assembly 1700 that may include one or more IC packages or other electronic components (e.g., a die) including one or more transistor cap-channel arrangements 100 and/or transistors 120 in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 14 (e.g., may include one or more transistor cap-channel arrangements 100 and/or transistors 120 in a die).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 15 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 15), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 15, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 12), an IC device (e.g., the IC device 1600 of FIG. 13), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 15, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 15 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 16 is a block diagram of an example electrical device 1800 that may include one or more transistor cap-channel arrangements 100 and/or transistors 120 in accordance with any of the embodiments disclosed herein. For example, any suitable ones of the components of the electrical device 1800 may include one or more of the IC device assemblies 1700, IC packages 1650, IC devices 1600, or dies 1502 disclosed herein. A number of components are illustrated in FIG. 16 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 16, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., DRAM), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded DRAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 is a back-end transistor, including: a channel material; an insulating material; and a cap material between the channel material and the insulating material, wherein the cap material includes copper, nickel, iron, cobalt, iridium, ruthenium, lanthanum, beryllium, lithium, or calcium.

Example 2 includes the subject matter of Example 1, and further specifies that the cap material further includes oxygen.

Example 3 includes the subject matter of any of Examples 1-2, and further specifies that the cap material is a first cap material, the back-end transistor further includes a second cap material different from the first cap material, the first cap material is between the channel material and the second cap material, the second cap material is between the first cap material and the insulating material, and the second cap material is different from the insulating material.

Example 4 includes the subject matter of Example 3, and further specifies that the second cap material includes oxygen.

Example 5 includes the subject matter of Example 4, and further specifies that the second cap material includes gallium, aluminum, hafnium, or zirconium.

Example 6 includes the subject matter of Example 3, and further specifies that the second cap material includes nitrogen.

Example 7 includes the subject matter of Example 6, and further specifies that the second cap material includes silicon.

Example 8 includes the subject matter of any of Examples 3-7, and further specifies that a thickness of the second cap material is between 5 Angstroms and 2 nanometers.

Example 9 includes the subject matter of any of Examples 3-8, and further includes: source/drain contacts extending through the insulating material toward the channel material, wherein the second cap material is not between the source/drain contacts and the channel material.

Example 10 includes the subject matter of any of Examples 1-9, and further specifies that a thickness of the cap material is between 1 Angstrom and 1 nanometer.

Example 11 includes the subject matter of any of Examples 1-10, and further specifies that the channel material includes a semiconductor material.

Example 12 includes the subject matter of any of Examples 1-11, and further specifies that the channel material includes indium gallium zinc oxide (IGZO).

Example 13 includes the subject matter of any of Examples 1-12, and further specifies that the insulating material includes an interlayer dielectric.

Example 14 includes the subject matter of any of Examples 1-13, and further specifies that the insulating material includes oxygen.

Example 15 includes the subject matter of any of Examples 1-14, and further specifies that the insulating material includes silicon or aluminum.

Example 16 includes the subject matter of any of Examples 1-13, and further specifies that the insulating material includes nitrogen.

Example 17 includes the subject matter of Example 16, and further specifies that the insulating material includes silicon.

Example 18 includes the subject matter of Example 17, and further specifies that the insulating material includes oxygen.

Example 19 includes the subject matter of any of Examples 1-18, and further includes: source/drain contacts extending through the insulating material toward the channel material.

Example 20 includes the subject matter of Example 19, and further specifies that the cap material extends between the source/drain contacts and the channel material.

Example 21 includes the subject matter of Example 19, and further specifies that the cap material does not extend between the source/drain contacts and the channel material.

Example 22 includes the subject matter of any of Examples 1-21, and further specifies that the cap material is in contact with the channel material.

Example 23 includes the subject matter of any of Examples 1-22, and further includes: a gate dielectric; and a gate electrode, wherein the gate dielectric is between the channel material and the gate electrode.

Example 24 includes the subject matter of any of Examples 1-23, and further specifies that the back-end transistor is in a metallization stack of an integrated circuit (IC) device.

Example 25 includes the subject matter of any of Examples 1-24, and further specifies that the back-end transistor is part of a memory cell.

Example 26 includes the subject matter of Example 25, and further specifies that the memory cell is a dynamic random access memory (DRAM) cell.

Example 27 is a back-end transistor, including: a channel material having a conductivity type; an insulating material; and a cap material between the channel material and the insulating material, wherein the cap material is different from the channel material and the insulating material, and the cap material has a conductivity type that is a same conductivity type as the channel material.

Example 28 includes the subject matter of Example 27, and further specifies that the conductivity type of the channel material and the cap material is n-type.

Example 29 includes the subject matter of Example 28, and further specifies that the cap material includes copper, nickel, iron, cobalt, iridium, ruthenium, lanthanum, beryllium, lithium, or calcium.

Example 30 includes the subject matter of Example 29, and further specifies that the cap material further includes oxygen.

Example 31 includes the subject matter of any of Examples 28-30, and further specifies that the cap material is a first cap material, the back-end transistor further includes a second cap material different from the first cap material, the first cap material is between the channel material and the second cap material, the second cap material is between the first cap material and the insulating material, and the second cap material is different from the insulating material.

Example 32 includes the subject matter of Example 31, and further specifies that the second cap material includes oxygen.

Example 33 includes the subject matter of Example 32, and further specifies that the second cap material includes gallium, aluminum, hafnium, or zirconium.

Example 34 includes the subject matter of Example 31, and further specifies that the second cap material includes nitrogen.

Example 35 includes the subject matter of Example 34, and further specifies that the second cap material includes silicon.

Example 36 includes the subject matter of any of Examples 31-35, and further specifies that a thickness of the second cap material is between 5 Angstroms and 2 nanometers.

Example 37 includes the subject matter of any of Examples 31-36, and further includes: source/drain contacts extending through the insulating material toward the channel material, wherein the second cap material is not between the source/drain contacts and the channel material.

Example 38 includes the subject matter of any of Examples 28-37, and further specifies that the channel material includes indium gallium zinc oxide (IGZO).

Example 39 includes the subject matter of Example 27, and further specifies that the conductivity type of the channel material and the cap material is p-type.

Example 40 includes the subject matter of Example 39, and further specifies that the cap material includes oxygen and any of copper, nickel, cobalt, lithium, or silver.

Example 41 includes the subject matter of any of Examples 39-40, and further specifies that the cap material is a first cap material, the back-end transistor further includes a second cap material different from the first cap material, the first cap material is between the channel material and the second cap material, the second cap material is between the first cap material and the insulating material, and the second cap material is different from the insulating material.

Example 42 includes the subject matter of Example 41, and further specifies that the second cap material includes oxygen or nitrogen.

Example 43 includes the subject matter of any of Examples 41-42, and further specifies that a thickness of the second cap material is between 5 Angstroms and 2 nanometers.

Example 44 includes the subject matter of any of Examples 41-43, and further includes: source/drain contacts extending through the insulating material toward the channel material, wherein the second cap material is not between the source/drain contacts and the channel material.

Example 45 includes the subject matter of any of Examples 39-44, and further specifies that the channel material includes oxygen and any of indium, zinc, gallium, hafnium, magnesium, aluminum, silicon, lanthanum, or zirconium.

Example 46 includes the subject matter of any of Examples 27-45, and further specifies that the channel material includes a semiconductor material.

Example 47 includes the subject matter of any of Examples 27-46, and further specifies that a thickness of the cap material is between 1 Angstrom and 1 nanometer.

Example 48 includes the subject matter of any of Examples 27-47, and further specifies that the insulating material includes an interlayer dielectric.

Example 49 includes the subject matter of any of Examples 27-48, and further specifies that the insulating material includes oxygen.

Example 50 includes the subject matter of any of Examples 27-49, and further specifies that the insulating material includes silicon or aluminum.

Example 51 includes the subject matter of any of Examples 27-48, and further specifies that the insulating material includes nitrogen.

Example 52 includes the subject matter of Example 51, and further specifies that the insulating material includes silicon.

Example 53 includes the subject matter of Example 52, and further specifies that the insulating material includes oxygen.

Example 54 includes the subject matter of any of Examples 27-53, and further includes: source/drain contacts extending through the insulating material toward the channel material.

Example 55 includes the subject matter of Example 54, and further specifies that the cap material extends between the source/drain contacts and the channel material.

Example 56 includes the subject matter of Example 54, and further specifies that the cap material does not extend between the source/drain contacts and the channel material.

Example 57 includes the subject matter of any of Examples 27-56, and further specifies that the cap material is in contact with the channel material.

Example 58 includes the subject matter of any of Examples 27-57, and further includes: a gate dielectric; and a gate electrode, wherein the gate dielectric is between the channel material and the gate electrode.

Example 59 includes the subject matter of any of Examples 27-58, and further specifies that the back-end transistor is in a metallization stack of an integrated circuit (IC) device.

Example 60 includes the subject matter of any of Examples 27-59, and further specifies that the back-end transistor is part of a memory cell.

Example 61 includes the subject matter of Example 60, and further specifies that the memory cell is a dynamic random access memory (DRAM) cell.

Example 62 is a computing device, including: a substrate; and an integrated circuit (IC) die coupled to the substrate, wherein the IC die includes a transistor having: a channel material, an insulating material, a first cap material, different from the channel material, between the channel material and the insulating material, second cap material, different from the first cap material, between the first cap material and the insulating material, and source/drain contacts, wherein the second cap material is between the source/drain contacts.

Example 63 includes the subject matter of Example 62, and further specifies that the second cap material is not between the source/drain contacts and the channel material.

Example 64 includes the subject matter of any of Examples 62-63, and further specifies that the first cap material has a conductivity type that is a same conductivity type as the channel material.

Example 65 includes the subject matter of any of Examples 62-64, and further specifies that the conductivity type of the channel material and the first cap material is n-type.

Example 66 includes the subject matter of Example 65, and further specifies that the first cap material includes copper, nickel, iron, cobalt, iridium, ruthenium, lanthanum, beryllium, lithium, or calcium.

Example 67 includes the subject matter of Example 66, and further specifies that the first cap material further includes oxygen.

Example 68 includes the subject matter of any of Examples 65-67, and further specifies that the second cap material includes oxygen.

Example 69 includes the subject matter of Example 68, and further specifies that the second cap material includes gallium, aluminum, hafnium, or zirconium.

Example 70 includes the subject matter of any of Examples 65-67, and further specifies that the second cap material includes nitrogen.

Example 71 includes the subject matter of Example 70, and further specifies that the second cap material includes silicon.

Example 72 includes the subject matter of any of Examples 65-71, and further specifies that a thickness of the second cap material is between 5 Angstroms and 2 nanometers.

Example 73 includes the subject matter of any of Examples 65-72, and further specifies that the channel material includes indium gallium zinc oxide (IGZO).

Example 74 includes the subject matter of any of Examples 62-64, and further specifies that the conductivity type of the channel material and the first cap material is p-type.

Example 75 includes the subject matter of Example 74, and further specifies that the first cap material includes oxygen and any of copper, nickel, cobalt, lithium, or silver.

Example 76 includes the subject matter of any of Examples 74-75, and further specifies that the second cap material includes oxygen or nitrogen.

Example 77 includes the subject matter of any of Examples 74-76, and further specifies that a thickness of the second cap material is between 5 Angstroms and 2 nanometers.

Example 78 includes the subject matter of any of Examples 74-77, and further specifies that the channel material includes oxygen and any of indium, zinc, gallium, hafnium, magnesium, aluminum, silicon, lanthanum, or zirconium.

Example 79 includes the subject matter of any of Examples 62-78, and further specifies that the channel material includes a semiconductor material.

Example 80 includes the subject matter of any of Examples 62-79, and further specifies that a thickness of the first cap material is between 1 Angstrom and 1 nanometer.

Example 81 includes the subject matter of any of Examples 62-80, and further specifies that the insulating material includes an interlayer dielectric.

Example 82 includes the subject matter of any of Examples 62-81, and further specifies that the insulating material includes oxygen.

Example 83 includes the subject matter of any of Examples 62-82, and further specifies that the insulating material includes silicon or aluminum.

Example 84 includes the subject matter of any of Examples 62-81, and further specifies that the insulating material includes nitrogen.

Example 85 includes the subject matter of Example 84, and further specifies that the insulating material includes silicon.

Example 86 includes the subject matter of Example 85, and further specifies that the insulating material includes oxygen.

Example 87 includes the subject matter of any of Examples 62-86, and further specifies that the first cap material extends between the source/drain contacts and the channel material.

Example 88 includes the subject matter of any of Examples 62-86, and further specifies that the first cap material does not extend between the source/drain contacts and the channel material.

Example 89 includes the subject matter of any of Examples 62-88, and further specifies that the first cap material is in contact with the channel material.

Example 90 includes the subject matter of any of Examples 62-89, and further includes: a gate dielectric; and a gate electrode, wherein the gate dielectric is between the channel material and the gate electrode.

Example 91 includes the subject matter of any of Examples 62-90, and further specifies that the transistor is in a metallization stack of an integrated circuit (IC) device.

Example 92 includes the subject matter of any of Examples 62-91, and further specifies that the transistor is part of a memory cell.

Example 93 includes the subject matter of Example 92, and further specifies that the memory cell is a dynamic random access memory (DRAM) cell.

Example 94 includes the subject matter of any of Examples 62-93, and further specifies that the computing device is a wearable or handheld computing device.

Example 95 includes the subject matter of any of Examples 62-94, and further specifies that the computing device further includes one or more communication chips and an antenna.

Example 96 includes the subject matter of any of Examples 62-95, and further specifies that the substrate includes a circuit board.

Example 97 includes the subject matter of Example 96, and further specifies that the circuit board is a motherboard.

1. A back-end transistor, comprising:
a channel material;
an insulating material; and
a cap material between the channel material and the insulating material, wherein the cap material includes copper, nickel, iron, cobalt, iridium, ruthenium, lanthanum, beryllium, lithium, or calcium.

2. The back-end transistor of claim 1, wherein the cap material further includes oxygen.

3. The back-end transistor of claim 1, wherein the cap material is a first cap material, the back-end transistor further includes a second cap material different from the first cap material, the first cap material is between the channel material and the second cap material, the second cap material is between the first cap material and the insulating material, and the second cap material is different from the insulating material.

4. The back-end transistor of claim 3, wherein the second cap material includes oxygen.

5. The back-end transistor of claim 4, wherein the second cap material includes gallium, aluminum, hafnium, or zirconium.

6. The back-end transistor of claim 3, wherein the second cap material includes nitrogen.

7. The back-end transistor of claim 6, wherein the second cap material includes silicon.

8. The back-end transistor of claim 3, wherein a thickness of the second cap material is between 5 Angstroms and 2 nanometers.

9. The back-end transistor of claim 3, further comprising:
source/drain contacts extending through the insulating material toward the channel material, wherein the second cap material is not between the source/drain contacts and the channel material.

10. The back-end transistor of claim 1, wherein a thickness of the cap material is between 1 Angstrom and 1 nanometer.

11. A back-end transistor, comprising:
a channel material having a conductivity type;
an insulating material; and
a cap material between the channel material and the insulating material, wherein the cap material is different from the channel material and the insulating material, and the cap material has a conductivity type that is a same conductivity type as the channel material.

12. The back-end transistor of claim 11, further comprising:
source/drain contacts extending through the insulating material toward the channel material.

13. The back-end transistor of claim 12, wherein the cap material extends between the source/drain contacts and the channel material.

14. The back-end transistor of claim 12, wherein the cap material does not extend between the source/drain contacts and the channel material.

15. The back-end transistor of claim 11, wherein the cap material is in contact with the channel material.

16. The back-end transistor of claim 11, wherein the back-end transistor is in a metallization stack of an integrated circuit (IC) device.

17. The back-end transistor of claim 11, wherein the back-end transistor is part of a memory cell.

18. The back-end transistor of claim 17, wherein the memory cell is a dynamic random access memory (DRAM) cell.

19. A computing device, comprising:
a substrate; and
an integrated circuit (IC) die coupled to the substrate, wherein the IC die includes a transistor having:
a channel material,
an insulating material,
a first cap material, different from the channel material, between the channel material and the insulating material,
a second cap material, different from the first cap material, between the first cap material and the insulating material, and
source/drain contacts, wherein the second cap material is between the source/drain contacts.

20. The computing device of claim 19, wherein the computing device further includes one or more communication chips and an antenna.
